(19) United States
(12) Patent Application Publication
(10) Pub. No.: US 2006/0275967 A1
(43) Pub. Date: Dec. 7, 2006

(54) Display device and manufacturing method thereof

(76) Inventors: Yoon-Ho Kang, Yongin-si (KR); Byoung-Joo Kim, Anyang-si (KR); Jang-Sub Kim, Suwon-si (KR); Seong-Gyu Kwon, Suwon-si (KR)

Correspondence Address: CANTOR COLBURN, LLP, 55 GRIFFIN ROAD SOUTH, BLOOMFIELD, CT, 06002, US

(21) Appl. No.: 11/433,260

(22) Filed: May 12, 2006

(30) Foreign Application Priority Data
May 12, 2005 (KR) 2005-39743

(51) Int. Cl. H01L 29/08; H01L 21/338

(52) U.S. Cl. 438/183; 257/40

(57) ABSTRACT

A color filter substrate includes a base substrate, a wall pattern having a lattice structure, a number of pixel regions defined by the wall pattern, a color filter layer formed in the pixel regions, and a dummy element layer. The base substrate includes an active area and an inactive area, and the dummy element layer includes a first dummy element layer in the active area and a second dummy element layer in the inactive area. The first dummy element is formed on a portion of the wall pattern. A manufacturing method of a color filter substrate includes: forming a wall pattern on a base substrate, wherein the wall pattern defines a number of pixel regions; printing at least one ink droplet over the one of the pixel regions; and printing at least one ink droplet on the wall pattern.

The present application claims priorities to Korean Patent Application No. 2005-39743, filed on May 12, 2005, and all the benefits accruing therefrom under 35 U.S.C. §119, and the contents of which in their entirety are herein incorporated by reference.

### BACKGROUND OF THE INVENTION

1. Technical Field

The present invention relates to a display device and a manufacturing method thereof, and more particularly to a display device having enhanced image quality and a manufacturing method thereof.

2. Description of the Related Art

Recently, flat panel displays, including liquid crystal displays (“LCDs”), organic light emitting displays (“OLEDs”) and plasma display panels (“PDPs”) have been widely used.

Flat panel display fabrication often includes a number of stacked thin film layers. For example, an LCD includes various thin film patterns such as thin film transistors, signal wires, pixel electrodes, black matrices and color filters. Also, an OLED includes various thin film patterns such as anode electrodes, electron injection layers, hole-injection layers, cathode electrodes and organic layers.

In order to form a patterned thin film layer, a thin film layer is deposited on a substrate by a chemical vapor deposition (“CVD”) process. Then, the thin film layer is patterned by various sub-processes, such as thin film deposition process, photo-resist pattern forming process, etching process and cleaning process.

However, the series of processes for a patterned thin film layer can be replaced by inkjet printing, thus reducing the process time and cost. However, forming thin film patterns by inkjet printing may cause some problems such as a non-uniform distribution of the thin film patterns. This problem can be explained with reference to FIG. 1.

FIG. 1A shows the shape of an ink 10 right after ink 10 is printed on the space between wall patterns 20. When ink 10 is dried after the printing, the drying speed is determined by the surrounding vapor density. Normally, the vapor density at the center area of ink 10 is higher than that at the edge area of ink 10. The drying speed of the edge area is higher than that of the center area, which leads more materials to go to the edge area, and after drying, the edge area will become thicker than the center area. This is called a “coffee ring effect”, which is shown in FIG. B. This non-uniform profile of the ink shape generally has an adverse effect on image quality.

### BRIEF SUMMARY OF THE INVENTION

The present invention is directed to a display device having enhanced image quality and a method of manufacturing such device. In accordance with an exemplary embodiment of the present invention, a color filter substrate includes a base substrate, a wall pattern having a lattice structure, a number of pixel regions defined by the wall pattern, a color filter layer formed in the pixel regions, and a dummy element layer. The base substrate includes an active area and an inactive area, and the dummy element layer includes a first dummy element layer in the active area and a second dummy element layer in the inactive area. The first dummy element is formed on a portion of the wall pattern.

In accordance with another exemplary embodiment of the present invention, a display device includes a base substrate, a first electrode lying over the base substrate, a wall pattern having a lattice structure, a number of pixel regions defined by the wall pattern, a light-emitting layer formed in the pixel regions, a dummy element layer, and a second electrode lying over the light-emitting layer. The base substrate includes an active area and an inactive area, and the dummy element layer includes a first dummy element layer in the active area and a second dummy element layer in the inactive area. The first dummy element layer is on a portion of the wall pattern.

In accordance with another exemplary embodiment of the present invention, a manufacturing method of a color filter substrate includes: forming a wall pattern on a base substrate, wherein the wall pattern defines a number of pixel regions; printing at least one ink droplet over the one of the pixel regions; and printing at least one ink droplet on the wall pattern. Another manufacturing method of a color filter substrate includes: forming a wall pattern on a base substrate, wherein the wall pattern defines a plurality of pixel regions; printing at least one ink droplet on a boundary between the wall pattern and the pixel regions; and printing at least one ink droplet on the pixel regions.

In accordance with another exemplary embodiment of the present invention, a manufacturing method of a display substrate includes: forming a first electrode over a base substrate; forming a wall pattern over the first electrode, wherein the wall pattern defines a number of pixel regions; printing at least one ink droplet on the pixel regions; and printing at least one ink droplet on the wall pattern. Another manufacturing method of a display substrate includes: forming a first electrode over a base substrate; forming a wall pattern over the first electrode, wherein the wall pattern defines a number of pixel regions; printing at least one ink droplet on a boundary between the wall pattern and the pixel regions; and printing at least one ink droplet over the pixel regions.

### BRIEF DESCRIPTION OF THE DRAWINGS

FIGS. 1A and 1B illustrate an ink shape in a conventional inkjet printing method.

FIG. 2 is a plan view illustrating a layout of a color filter substrate according to an exemplary embodiment of the present invention.

FIG. 3 is a cross-sectional view of the color filter substrate of FIG. 2 along line I-I′.

FIG. 4 is a cross-section view of the color filter substrate of FIG. 2 along line II-II′.

FIG. 5, 6 and 8 explains a color filter substrate manufacturing method according to an exemplary embodiment of the present invention.

FIG. 7 is a cross-section view of the color filter substrate of FIG. 6 along line IV-IV′.

FIG. 9 is a cross-sectional view of the color filter substrate of FIG. 8 along line V-V′.

FIGS. 10A, 10C and 10B, 10D are top plan views and cross-sectional views, respectively, illustrating an advantage according to an exemplary embodiment of the present invention.

FIGS. 11, 12 and 13 illustrate inkjet printing methods according to the present invention.

FIG. 14 shows another cross-sectional view of the color filter substrate of FIG. 2 along line II-II′ according to another exemplary embodiment of the present invention.

FIG. 15 shows a layout of a display substrate for an OLED according to another exemplary embodiment of the present invention.

FIG. 16 is a cross-sectional view of the display substrate of FIG. 15 along the line III-III′.

### DETAILED DESCRIPTION OF THE INVENTION

The present invention is described more fully hereinafter with reference to the accompanying drawings, in which exemplary embodiments of the present invention are shown. The present invention may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be described with reference to the accompanying drawings.

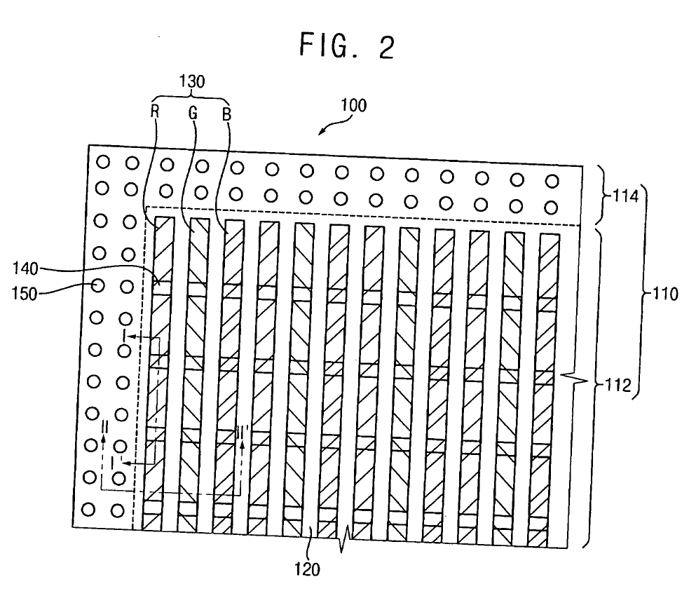

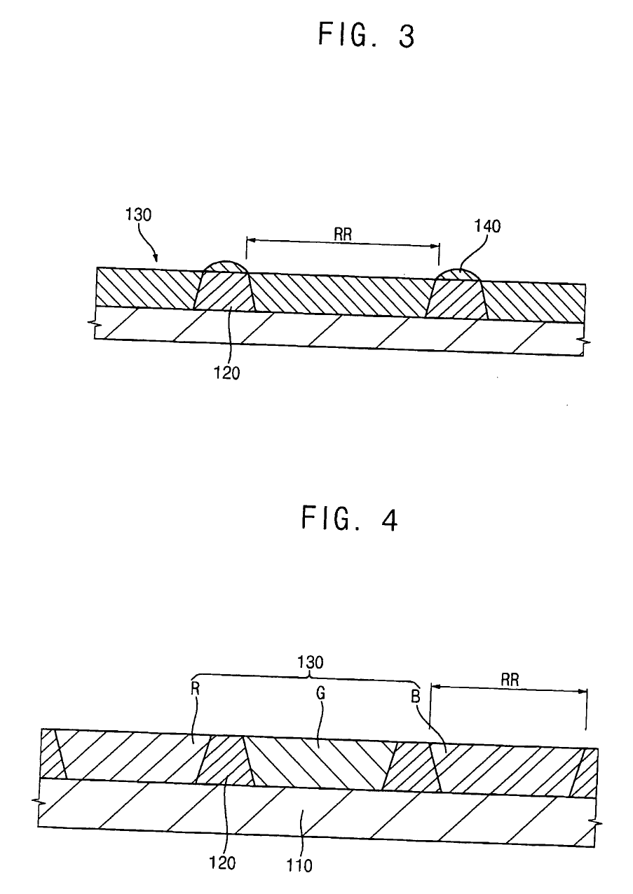

FIGS. 2 to 4 illustrate a color filter substrate 100 for LCD in accordance with an exemplary embodiment of the present invention. FIG. 2 shows a layout of color filter substrate 100, FIG. 3 is a cross-sectional view of the color filter substrate 100 of FIG. 2 along line I-I′, and FIG. 4 is a cross-sectional view of the color filter substrate 100 of FIG. 2 along line II-II′.

The color filter substrate 100 includes a base substrate 110, a wall pattern 120, a color filter layer130 and a dummy element layer 140.

The base substrate 110 is made of a transparent material, such as glass or plastic. The base substrate 110 includes an active area 112 and an inactive area 114, which surrounds the active area 112.

The wall pattern 120, having a lattice structure, is formed in the active area 112. According to the present exemplary embodiment, the wall pattern 120 is often made of an organic material mixed with a light-absorbing material such as carbon black. However, the wall pattern can also be made of Cr or Cr/CrOx.

The color filter layer 130 is formed in a pixel area RR defined by the wall pattern 120. The color filter layer 130 includes red color filters R, green color filters G and blue color filters B.

The dummy element layer 140 is formed on a portion of the wall pattern 120 between two adjacent color filters R, G or B in the same column, as shown in FIGS. 2 and 3. However, in other embodiments, the dummy element layer 140 may be formed between adjacent color filters R, G or B in the same row. The dummy element 140 on the wall pattern 120 makes the structure of color filters R, G or B in the pixel area RR uniform. In other words, the dummy element 140 on the wall pattern 120 facilitates drying of ink in the color filter layer 130 to provide a uniform thickness of the color filter layer 130 discussed below.

Another dummy element layer 150 is formed in the inactive area 114 so as to make the structure of the color filter layer 130 uniform near the inactive area 114. Again, the addition of a dummy element layer 150, like the dummy element layer 140, in the inactive area facilitates drying of ink in the color filter layer 130 to provide a uniform thickness of the color filter layer 130 discussed below.

In this exemplary embodiment, both dummy element layer 140 in the active area 112 and dummy element layer 150 in the inactive area 114 are formed together. However, it is also possible to form only dummy element layer 140 or only dummy element layer 150.

The dummy element layer 140 and 150 regulate the distribution of drying speed of the color filter layer 130 in the pixel area RR, so as to enhance the thickness uniformity of the color filter layer 130. Preferably, the dummy element layer 140 and 150 are formed of the same material as the color filter layer 130.

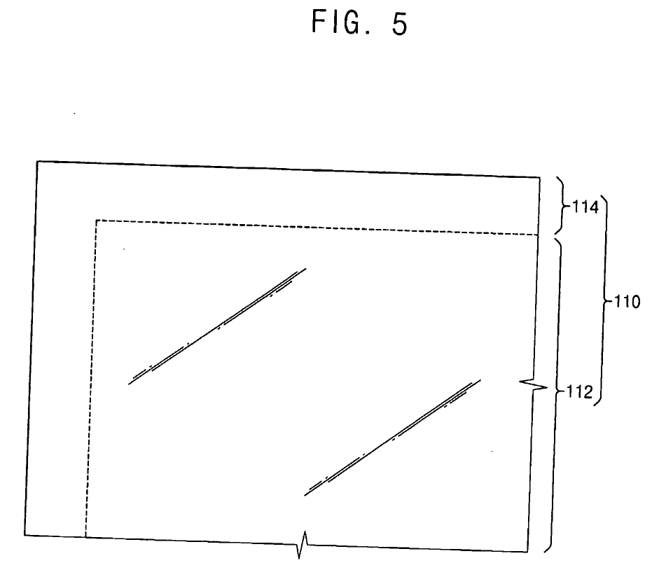

Referring to FIGS. 5 to 14, a manufacturing method of the color filter substrate 100 is explained.

Referring to FIG. 5, the base substrate 110 is prepared. The base substrate 110 is made of a transparent material, such as glass or plastic. The base substrate 110 includes the active area 112 and the inactive area 114, which surrounds the active area 112.

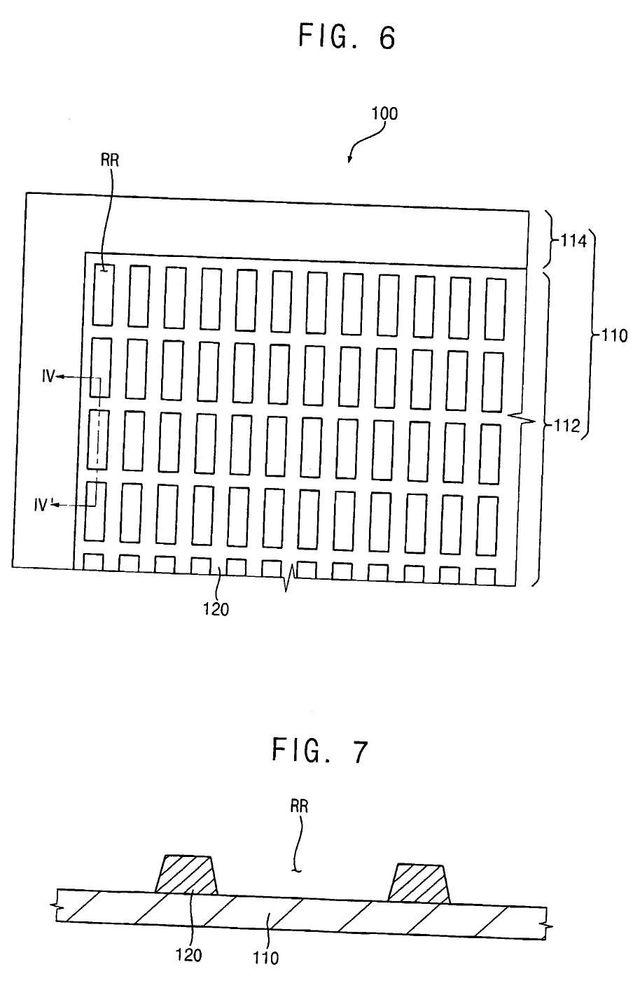

Referring to FIGS. 6 and 7, the wall pattern 120 having a lattice structure is formed in the active area 112. In order to form the wall pattern 120, an organic material including black resin is coated on the base substrate 110. Next, the coated organic material layer is patterned using a known photolithography method. The wall pattern 120 defines the pixel area RR, where the color filters R, G and B are formed.

In the present exemplary embodiment, the wall pattern 120 is made of an organic material mixed with light-absorbing material such as carbon black. Alternatively, the wall pattern 120 may be made of Cr or Cr/CrOx. In this case, Cr or Cr/CrOx is deposited by CVD or sputtering, and the wall pattern 120 is formed by a known photolithography method.

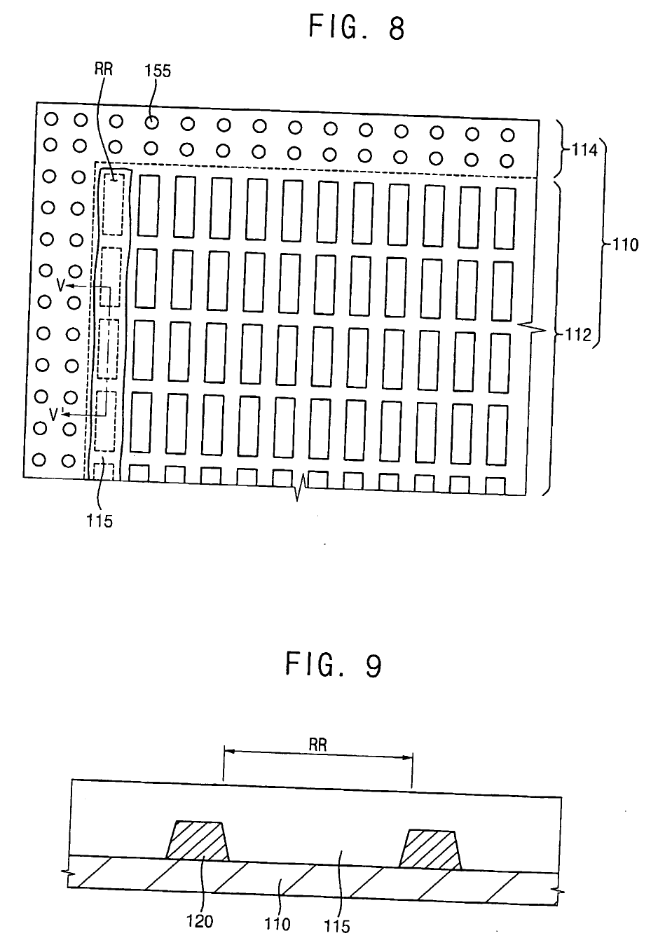

Referring to FIGS. 8 and 9, inkjet printing forms an ink layer 115 printed on the base substrate 110 and the wall pattern 120. FIG. 9 is a cross-sectional view of FIG. 8 along line V-V′. The ink layer 115 is formed on the pixel area RR and the wall pattern 120 along a column direction of the color filter substrate 100, as illustrated in FIG. 8. The inkjet printing is repeated column by column. After the drying process, the ink layer 115 on the pixel area RR becomes the color filter layer 130, and the ink layer 115 on the wall pattern 120 becomes the dummy element layer 140. The ink layer 115 is also formed and dried in the inactive area 114, so as to form the dummy element layer 150.

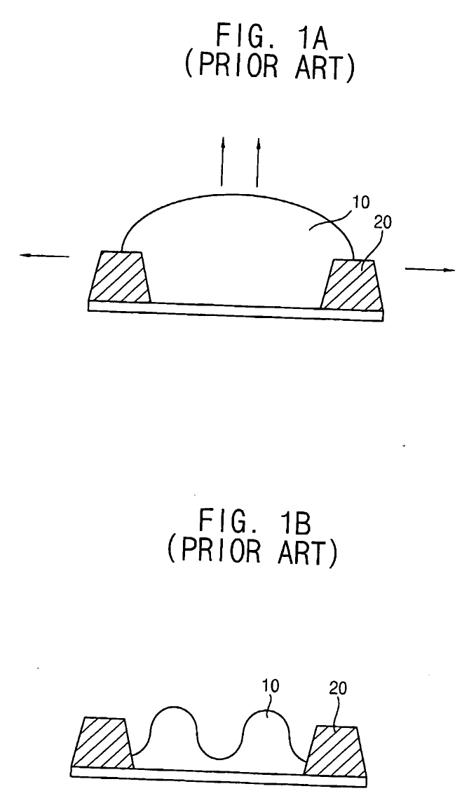

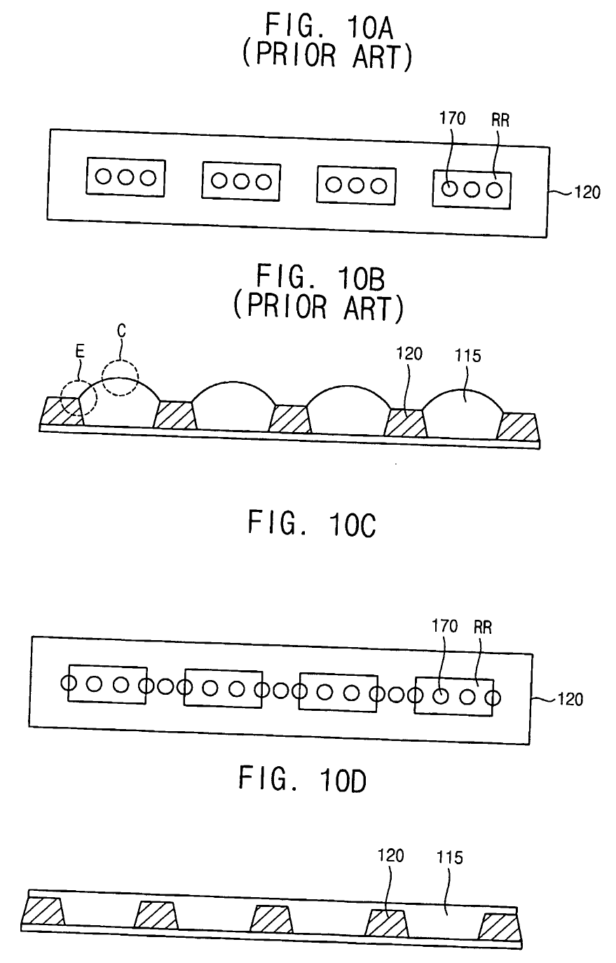

FIGS. 10A, 10C and 10B, 10D are top plan views and cross-sectional views, respectively, illustrating an advantage according to an exemplary embodiment of the present invention, as compared with the prior art (FIGS. 10A and 10B). As shown in FIGS. 10A and 10B, when ink droplets 170 are printed only within the pixel area RR, the ink layer 115 is formed only in the pixel region RR. In this case, as explained above with respect to FIG. 1, the non-uniform profile of ink pattern due to the drying speed difference between the center area “C” and the edge area “E” of FIG. 10B occurs. FIGS. 10C and 10D, show that the ink droplets 170 are printed not only in the pixel region RR but also on a portion of the wall pattern 120. In this case, the uniform drying speed of the ink layer 115 between the center of the pixel region RR and the edge of the pixel region RR can produce the color filter layer 130 with a uniform profile and thickness after drying.

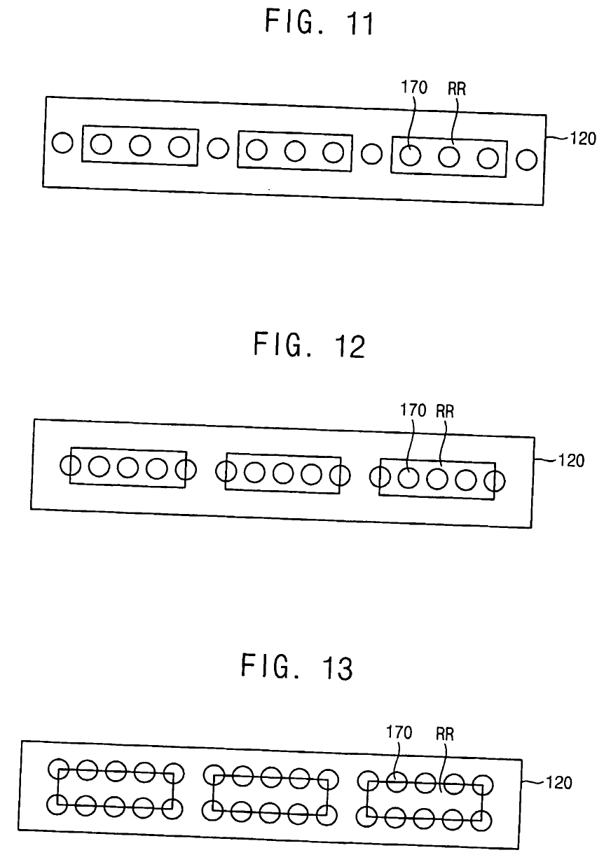

FIGS. 11 to 13 shows exemplary printing sequences of the ink droplets 170 in accordance with other exemplary embodiments of the present invention, which form the ink layer 115 not only in the pixel region RR but also on the wall pattern 120.

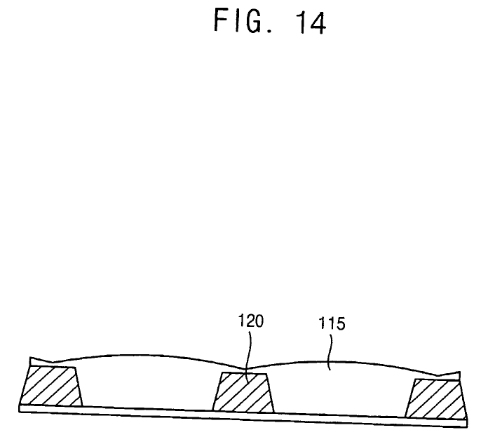

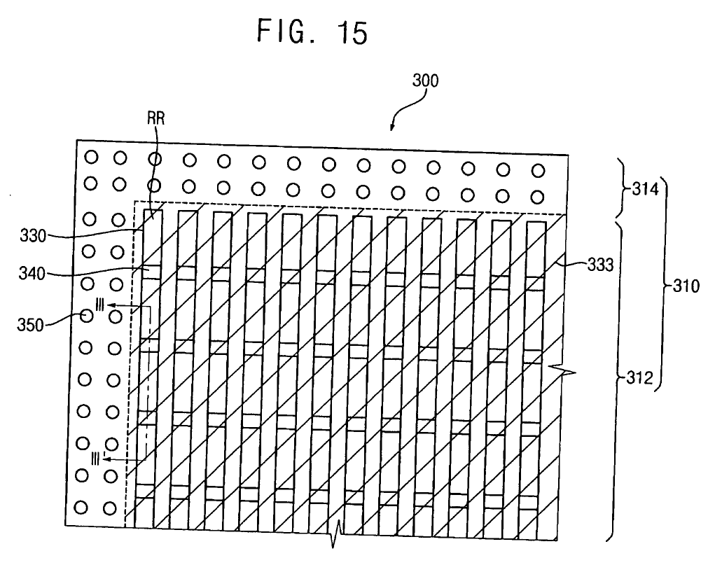

The ink droplets 170 printed on a portion of the wall pattern 120 can reduce the drying speed difference of the ink layer 115 between the center of the pixel region RR and the edge of the pixel region RR. Accordingly, the color filter layer 130 with a uniform profile and/or uniform thickness is produced after drying. The ink layer 115 on the wall pattern 120 remains as the dummy element layer 140 after drying, as shown in FIGS. 3 or 14, depending on the quantity of the ink layer 115 on the wall pattern 120 before drying.

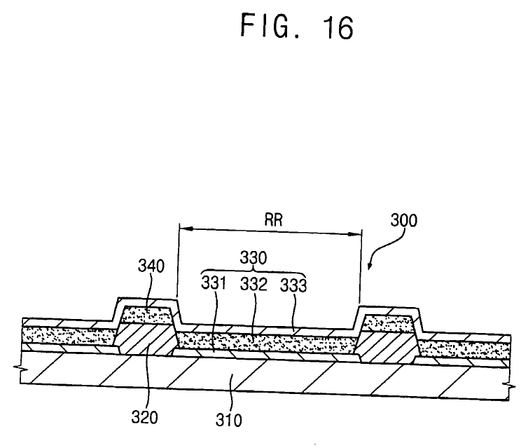

FIGS. 15 and 16 illustrate a display substrate 300 for an OLED according to another exemplary embodiment of the present invention. FIG. 15 is a plan view illustrating a layout of the display substrate 300, and FIG. 16 is a cross-sectional view of the display substrate 300 of FIG. 15 along the line III-III′.

The display substrate 300 includes a base substrate 310, a wall pattern 320, a light-emitting area 330 and a dummy element layer 340.

The base substrate 310 can be divided into an active area 312 and an inactive area 314. The inactive area 314 surrounds the active area 312.

The wall pattern 320, having a lattice structure, is formed in the active area 312. According to the present exemplary embodiment, the wall pattern 320 is made of an organic material mixed with a light-absorbing material such as carbon black, but the wall pattern 320 alternatively can be made of Cr or Cr/CrOx.

The light-emitting area 330, which is formed in a pixel region RR, includes a first electrode 331, a light-emitting layer 332 and a second electrode 333.

The first electrode 331 is formed of a transparent conductive material, such as indium tin oxide (ITO) or indium zinc oxide (IZO) by sputtering or CVD on the base substrate 310. After the formation of the wall pattern 320, the light-emitting layer 332 and the dummy element layer 340 are formed on the first electrode 331 in the pixel area RR and on the wall pattern 320, respectively, in the similar way that the color filter layer 130 was formed with respect to FIGS. 2 to 14. The dummy element layer 340 on the wall pattern 320 makes the structure of the light-emitting layer 332 uniform in the pixel area RR. In other words, the dummy element layer 340 reduces the drying speed difference of the light-emitting layer 332 between the center of the pixel region RR and the edge of the pixel region RR. Accordingly, the light emitter area 330 dries with a uniform profile and/or uniform thickness.

Another dummy element layer 350 is also formed in the inactive area 314 to make the structure of the light-emitting layer 332 uniform near the inactive area 314 in the same manner that a the dummy element layer 340 discussed above.

Dummy element layers 340 and 350 regulate the distribution of drying speed of the light-emitting layer 332 in the pixel region RR, thus enhancing the thickness uniformity of the light-emitting layer 332. In exemplary embodiments, dummy element layers 340 and 350 are formed of the same material as the light-emitting layers 332.

The second electrode 333 is formed of a metal, such as Al or Al alloy by sputtering over the light-emitting layer 332, so that light-emitting area 330 is formed completely.

Although the illustrative exemplary embodiments have been described herein with reference to the accompanying drawings, it is to be understood that the present invention is not limited to those specific exemplary embodiments, and that various changes and modifications may be affected therein by one of ordinary skill in the related art without departing from the spirit and scope of the present invention. All such changes and modifications are intended to be included within the scope of the present invention as defined in the appended claims.

What is claimed is:

1. A color filter substrate comprising:
a base substrate;
a wall pattern having a lattice structure defining a plurality of pixel regions;
a color filter layer formed in the pixel regions; and
a dummy element layer.

2. The color filter substrate of claim 1, wherein the base substrate comprises an active area and an inactive area, and wherein the dummy element layer comprises a first dummy element layer in the active area and a second dummy element layer in the inactive area.

3. The color filter substrate of claim 2, wherein the first dummy element is on a portion of the wall pattern.

4. The color filter substrate of claim 1, the wall pattern includes a light-absorbing material.

5. The color filter substrate of claim 1, the color filter layer and the dummy element layer are made of the same material.

6. A display device comprising:
a base substrate;
a first electrode lying over the base substrate;
a wall pattern having a lattice structure defining a plurality of pixel regions;
a light-emitting layer formed in the pixel regions;
a dummy element layer; and
a second electrode lying over the light-emitting layer.

7. The display device of claim 6, wherein the base substrate comprises an active area and an inactive area, and wherein the dummy element layer comprises a first dummy element layer in the active area and a second dummy element layer in the inactive area.

8. The display device of claim 7, wherein the first dummy element layer is on a portion of the wall pattern.

9. The display device of claim 6, the light-emitting layer and the dummy element layer are made of the same material.

10. A manufacturing method of a color filter substrate comprising:
forming a wall pattern on a base substrate, the wall pattern defining a plurality of pixel regions;
printing at least one ink droplet over the one of the pixel regions; and
printing at least one ink droplet on the wall pattern.

11. The manufacturing method of a color filter substrate of claim 10, wherein the base substrate comprises an active area and an inactive area, and wherein the method further comprises printing at least one ink droplet over the inactive area.

12. The manufacturing method of a color filter substrate of claim 10, wherein the wall pattern includes a light-absorbing material.

13. A manufacturing method of a color filter substrate comprising:
forming a wall pattern on a base substrate, wherein the wall pattern defines a plurality of pixel regions; and
printing at least one ink droplet on a boundary between the wall pattern and the pixel regions.

14. The manufacturing method of a color filter substrate of claim 13, further comprising printing at least one ink droplet on the pixel regions.

15. The manufacturing method of a color filter substrate of claim 13, wherein the wall pattern includes a light-absorbing material.

16. A manufacturing method of a display substrate comprising:
forming a first electrode over a base substrate;
forming a wall pattern over the first electrode, the wall pattern defining a plurality of pixel regions;
printing at least one ink droplet on the pixel regions; and
printing at least one ink droplet on the wall pattern.

17. The manufacturing method of a display substrate of claim 16, wherein the base substrate comprises an active area and an inactive area, and wherein the method further comprises printing at least one ink droplet on the inactive area.

18. A manufacturing method of a display substrate comprising:
forming a first electrode over a base substrate;
forming a wall pattern over the first electrode, the wall pattern defining a plurality of pixel regions; and
printing at least one ink droplet on a boundary between the wall pattern and the pixel regions.

19. The manufacturing method of a display substrate of claim 18, further comprising printing at least one ink droplet over the pixel regions.
